(19) United States
(12) Patent Application Publication
(10) Pub. No.: US 2025/0374658 A1
(43) Pub. Date: Dec. 4, 2025

(54) METHOD FOR PRODUCING BIPOLAR TRANSISTORS WITH NON-SELECTIVE BASE EPITAXY

(71) Applicant: IHP GmbH-Innovations for High Performance Microelectronics/Leibniz-Instittut für innovative Mikroele, Frankfurt (Oder) (DE)

(72) Inventors: Bernd HEINEMANN, Frankfurt (Oder) (DE); Holger RÜCKER, Frankfurt (Oder) (DE)

(21) Appl. No.: 18/719,596

(22) PCT Filed: Dec. 15, 2022
(86) PCT No.: PCT/EP2022/086213

§ 371 Date: Aug. 1, 2024

(30) Foreign Application Priority Data
Dec. 16, 2021 (EP) 21215189.8

(51) Int. Cl. H10D 84/40; H10D 10/01; H10D 10/40; H10D 10/80; H10D 84/01

(52) U.S. Cl. CPC H10D 84/401; H10D 10/021; H10D 10/056; H10D 10/40; H10D 10/821; H10D 84/0109

(57) ABSTRACT

A process for the production of high-speed and high-voltage transistors includes implementing a masked first and/or second ion implantation in active areas of a substrate for forming a collector area of the first conductivity type, depositing an insulator layer on a surface of the substrate and defining collector windows, depositing a buffer layer in the collector windows and a base layer of a second conductivity type, depositing an insulator layer over a cap layer of the buffer layer, implementing ions of a same doping type as the collector of the transistor, depositing a silicon layer and forming a base-emitter spacer within the emitter window, exposing a surface of the emitter window, performing epitaxial deposition of a emitter layer of the first conductivity type, depositing of an insulator layer, exposing the cap layer, and patterning parts of the buffer layer, the base layer and the cap layer.

### TECHNICAL FIELD

The invention pertains to processes for producing bipolar transistors. The processes concern more particularly the enablement of an optionally alternative or joint production of different types of bipolar transistors for high-speed applications and for high-voltage applications as part of a bipolar production procedure or a BiCMOS production procedure. The invention relates, furthermore, to a bipolar semiconductor device and a BiCMOS semiconductor device.

### PRIOR ART

Bipolar transistors are employed multifariously in integrated analog and digital electronic circuits. Bipolar transistors are utilized in particular on account of their short switching times for high-speed applications. The performance capability of bipolar transistors in the high-speed segment was able to be boosted considerably by vertical and lateral scaling of the transistor dimensions and by the introduction of base layers produced epitaxially.

A particular contribution to this has been made by the development of heterojunction bipolar transistors (HBTs). With heterojunction bipolar transistors, the emitter layer and base layer consist of different semiconductor materials, with the emitter possessing a larger bandgap than the base. An example of this are SiGe heterojunction bipolar transistors, in which the emitter consists of silicon (Si) and the base contains a silicon-germanium alloy (SiGe).

The possibility of further improving the radiofrequency properties of modern SiGe HBTs is dependent on the success or otherwise of exploiting the potential for lateral and vertical scaling in order to minimize internal transit times and charging times and also to minimize external parasitic effects, such as the external base resistance, the resistances of emitter and collector, or the external base-emitter and base-collector capacitances.

A variety of approaches are taken to the production of SiGe HBTs in the high-speed segment. The nature of the base epitaxy has considerable consequences for the design of the production procedure. One technology which has proven particularly attractive is that known as the double-polysilicon technology with selective base epitaxy, as it can be used, at moderate cost and complexity, to produce transistors which in key parts, namely external base terminal to emitter and emitter to collector, are self-aligned. The group of technologies involving differential (non-selective) base epitaxy (NSEG) (for non-selective epitaxial growth) includes not only self-aligned but also non-self-aligned base-emitter arrangements. In order to decouple the vertical expansion of the external base layer from the thickness requirements of the internal base layer and of the undoped cap layer situated above it, processes with reinforcement of the base terminal area have become established for NSEG technologies. Another means of delimiting the manufacturing procedures for high-speed HBTs concerns the nature of the lateral isolation of the highly doped collector layer. In general, epitaxially buried, highly conductive areas are introduced which are separated from the substrate laterally by deep trenches (DT), filled wholly or partly with insulator material. The SiGe HBTs that are presently the fastest are produced without the structural feature of a “DT-isolated, epitaxially buried sub-collector”. In these systems, the lateral isolation of a relatively shallow, highly doped collector layer with respect to the substrate is taken on by STI areas and an insulator layer above the substrate surface is used for the dielectric isolation of the external base layer. The prior art in connection with processes for the realization of high-speed (HS) SiGe HBTs and their integration in CMOS technologies also includes the provision of bipolar transistors having relatively high emitter-collector and/or collector-base breakthrough voltages (HV transistors). The production steps for the HS transistors are usually adopted largely for this purpose. When fabricating the HV transistors, attention must be paid to the manner in which higher levels of collector doping in the vicinity of the base are eliminated and replaced by suitable weak concentrations.

Described in DE 10358046 is a bipolar transistor with non-selectively deposited base layer and a process for its production, wherein the internal transistor area is located jointly with the collector terminal area and collector contact area in a singly coherent active area of the substrate wafer and includes a dielectrically isolated, epitaxially reinforced base terminal separated self-aligningly from the emitter by spacers.

Specific attention is paid in this regard to the shaping of the electrically insulating base-emitter spacers. By means of suitable doping processes for the reinforced base terminal layer, this construction permits low-capacitance reduction in the base resistance, thereby boosting the limiting frequency of the power amplification. This limiting frequency is referred to as fₘₐₓ. Furthermore, a reduction in the base resistance leads to an improvement in the noise properties of the transistor. In connection with the transistor construction described in DE 10358046 and with its production, Rücker, H., et al.: “A 0.13 μm SiGe BiCMOS Technology featuring f_{T}/fₘₐₓ of 240/330 GHz and gate delays below 3 ps”, IEEE Journal of Solid State Circuits, vol. 45, pp. 1678-1686 September 2010, reports on the fabrication not only of a high-speed SiGe (HS) HBT but also of a high-voltage (HV) transistor, where lithography masks are utilized efficiently for the collector doping of lower-lying n-wells of the CMOS arrangements and shallow trench isolation (STI) for the lateral separation of internal transistor and collector terminal.

The pathway set out in the prior art to improving the high-speed properties of an SiGe HBT in conjunction with fabrication-cost-efficient realization of an HV bipolar transistor offered considerable potential for emitter widths of down to about 180 nm. Further advances in speed through lateral and vertical size reduction are barely achievable with the means employed in Rucker et al. The wet-chemical etching characteristics of LPCVD oxide (TEOS) coatings result in a considerable widening of the dimension, defined by the dry etching, of the emitter and collector windows of the HS HBTs. On the other hand, the possibility afforded in the prior art of responding to changes in spacer formation with reduced step height between the emitter polylayer and the reinforced base terminal area presents the device engineer with problems. One unsatisfactory aspect of the prior art set out here is also the lack of possibility to design the sidewall of an insulation layer in such a way that, on subsequent Si epitaxy, the formation of facets in the grown Si is avoided and the manifestation of low-capacitance and low-resistance forms of the laterally adjacent isolation area is promoted. Furthermore, the design of the HV transistor on the collector side with collector terminal areas running below the STI leads to disadvantages in the radiofrequency properties. It would be advantageous to have a highly conductive collector layer, connecting the base-collector charge zone and the collector contact, and to have a lower-capacitance design of the collector-substrate diode.

### DESCRIPTION OF THE INVENTION

With respect to the known prior art, therefore, the technical problem arises of providing processes for producing a further laterally scaled bipolar transistor, including a second version of a bipolar transistor with a higher base-collector and/or collector-emitter breakthrough voltage. These processes shall improve the radiofrequency suitability of the bipolar transistors by means of smaller lateral and vertical dimensions, and shall ensure sufficient fabrication reliability in terms of tolerances and the functional yield.

Furthermore, production processes are sought that guarantee the desired protection of the T-shaped emitter, largely independently of its height and shape, during an implantation or the selective reinforcement of the base terminal area.

This problem is solved, according to a first aspect of the invention, by a process for producing high-speed bipolar transistors, hereinafter HS transistors, or/and high-voltage bipolar transistors, hereinafter HV transistors, as part of the implementation of a bipolar or BiCMOS production procedure, which is defined in claim 1. Reference symbols added subsequently are to be understood merely as a reference to illustrative possibilities for implementation in accordance with the working examples, and not as a limitation thereto.

The process comprises the following steps:
a. provision of a substrate having active areas and shallow trenchlike field isolation areas which surround the active areas;
b. subsequently, optionally,
   b1. implementation of a masked first ion implantation for forming a high-conductivity HV collector area of a first conductivity type in the active areas intended for the HV transistors; or/and
   b2. implementation of a masked second ion implantation for forming a high-conductivity HS collector area of the first conductivity type in the active areas intended for the HS transistors; wherein steps b1 and b2, if they are both performed, are implemented in any desired order;
c. deposition of insulator layers on the substrate surface and definition of collector windows as internal transistor areas of the HS and HV transistors;
d. selective epitaxial deposition of a buffer layer in the collector windows thus defined, and subsequently non-selective epitaxial deposition of a monocrystalline base layer of a second conductivity type, opposite to the first, and of a monocrystalline cap layer on the buffer layer, where during the non-selective epitaxial deposition, a polycrystalline layer stack grows at the same time on the insulator layers, and where the deposition of the buffer layer, the base layer and the cap layer takes place in one joint or in two separate epitaxy steps;
e. deposition of an insulator layer stack over the cap layer and subsequent definition of an active emitter domain, referred to hereinafter as emitter window, by opening of a window in insulator layers of the insulator layer stack;
f. implementation of ion implantations of the same doping type as the collector for the formation of selectively implanted collector areas of the HS transistors, hereinafter HS-SIC doping, and/or of selectively implanted collector areas of the HV transistors, hereinafter HV-SIC doping, optionally after the deposition of the buffer layer if the depositions in step d are performed in two separate epitaxy steps, or after opening of the emitter windows in step e, comprising
   f1. selective ion implantation in internal collector areas of the HS transistors where provided, the HV transistors where provided being protected from the implantation by a resist mask or by the insulator stack,
   f2. selective ion implantation in internal collector areas of the HV transistors where provided, the HS transistors where provided being optionally covered by a resist mask or likewise undergoing this implantation of the internal collector areas,
   f3. choice of the implantation conditions in such a way that a vertical extent of the base-collector space charge zone in the HV transistor is greater than in the HS transistor;
g. deposition of a silicon dioxide layer and formation of base-emitter spacers within the emitter window by partial anisotropic back-etching of the silicon dioxide layer by means of a dry etching process, and formation of auxiliary spacers in the emitter window, in particular by deposition of a silicon nitride layer and subsequent anisotropic back-etching with stopping on the remaining part of the layer;
h. exposure of a surface in the emitter window, formed by the cap layer, and subsequent removal of the auxiliary spacers;
i. epitaxial deposition of a highly doped, monocrystalline or polycrystalline emitter layer of the first conductivity type;
j. deposition of an insulator layer sequence and patterning of the insulator layer sequence, the emitter layer and the insulator layer for forming a T-shaped emitter, and production of lateral spacers at the outward-facing side faces of the emitter layer and of the insulator layer;
k. exposure of the cap layer in regions outside the emitter and selective epitaxy of a height extension of a base terminal layer of the polycrystalline layer stack with in situ doping of the same conduction type as the base; the conductivity of the base terminal layer may optionally be increased by a following ion implantation;
l. patterning of the parts of the buffer, base, cap and heightened base terminal layers deposited on the base terminal areas, for the removal of said layers from collector terminal areas.

In the process of the invention, in the context of a bipolar or BiCMOS technology, not only HS transistors, i.e. bipolar transistors with particularly high limiting frequencies f_{T} and fₘₐₓ, but also HV transistors, i.e. bipolar transistors with relatively high breakthrough voltage, are fabricated.

The invention improves various aspects of the HS and HV bipolar transistor devices described in the prior art and of their production. Working examples of the process of the present invention overcome production disadvantages of a known technology, described at the beginning, that produces bipolar transistors with non-selective base deposition, their collector area being surrounded laterally by shallow field isolation areas, and which possess a self-aligned base-emitter arrangement and also epitaxially reinforced base terminal areas.

On the one hand, the arrangement of the HV transistor known from the prior art, with an additional shallow field isolation area fabricated in STI technology and arranged between the internal transistor area and the collector contact, is replaced through a construction which in cross section corresponds to that of the high-speed transistor. In other words, in the active areas intended for the HV transistors, there is in each case only one coherent highly conductive HV collector area of a first conductivity type. The specific base-collector doping profile needed for this transistor is introduced by means of an additional procedural sequence for the opening and implantation of the HV collector areas.

Key advantages of this process regime by comparison with the known solution described at the outset include a further-improved avoidance of leakage current at the lateral base-collector junction and also a reduction in the collector resistance, in the base-collector capacitance and in the collector-substrate capacitance. Accordingly, both the high-voltage electric strength and radiofrequency properties are improved.

Advantages are also achieved by the process of the invention with replacement of individual silicon dioxide layers by layer combinations of multiple insulator layers in step c and in step g. Specifically, this relates (step c) to the silicon oxide layer used in the prior art between the external base terminal area and the collector terminal area, and also (step g) to the layer from which the base-emitter spacer is formed. In particular, different wet etching rates of the insulator layers in step c are important for the shaping of advantageous sidewalls of the collector windows. With exploitation of the differences in etching rate of different types of oxide on wet-chemical treatment, and of the properties of anisotropic dry etching processes, success is also achieved in step g, by means of the layer combination employed in accordance with the invention, in comparison with the prior art, with similar lithographic pattern width, in reducing the widening of emitter and/or collector window and hence in generating smaller lateral dimensions. At the same time, modifications according to the invention are utilized for designing as part of steps c and g shapes of the insulator sidewalls at the collector and/or emitter window that are favorable for the electrical properties.

Described below are embodiments of the process of the invention. For better orientation, the description of the embodiments also uses, where it appears useful, reference symbols, which are introduced in more detail in the subsequent description of figures. The sole purpose of this is to assist understanding of the respective embodiments, and it is not intended to limit their subject matter by the specific features of the working examples elucidated later on below in the description of figures, and certainly not to imply the use of their further features in the embodiments respectively described.

The implementation of the process of the present invention takes place preferably in the alphabetical order indicated by the letters placed in front of the steps in order to break down the process of the invention. This expressly does not imply that the individual steps must necessarily be performed directly one after another. In process variants, intermediate steps are possible between individual process steps of the process of the invention. For example, such intermediate steps and process variants are apparent from the subsequent description of working examples. As measures routine in the art, other additional steps which may be envisaged optionally in the process regime and which are technically rational do not require any express mention.

In one embodiment of the process of the invention, after the formation of the collector areas of the HV or/and HS transistors, in step b, additionally, a silicon buffer layer is selectively epitaxially deposited on the exposed collector areas.

The masked implantation steps b1 and b2, if they are both performed, may be implemented in any desired order. Advantageously, before these masked implantation steps are implemented, an auxiliary layer (i) is deposited on the substrate surface, followed by successive opening of the auxiliary layer in transistor areas of the bipolar transistors where implantation is to take place, while any existing areas of the substrate with MOS transistors remain covered by the auxiliary layer. The auxiliary layer is preferably embodied as a layer stack of different materials, comprising in particular at least one silicon dioxide layer and at least one silicon nitride layer.

The ion implantations of the collector areas of the HS-HBTs and of the HV-HBTs in step b are preferably each implemented such that a border of a collector-substrate space charge zone situated closer to the substrate surface is embodied less deep in the substrate than a bottom of the field isolation areas.

In a further embodiment, the crystal lattice of the Si substrate, disrupted during the collector implantation in step b, undergoes low-defect reconstruction by means of a heat treatment.

In a further embodiment of the process, the production of the insulator layers in step c comprises production of three insulator layers. It is, however, also possible to use only two insulator layers, by using a single layer instead of the layer sequence i1-i2.

The deposition of three insulator layers, for the definition of collector windows as internal transistor areas of the HS and HV transistors, advantageously comprises the deposition initially of a first SiO₂ layer and thereafter of a second SiO₂ layer, which by comparison with the first SiO₂ layer is more etch-stable with respect to wet etching in dilute hydrofluoric acid. In this process regime, the ratio set for the etching rates of the first and second SiO₂ layers is preferably greater than 1.5, more preferably greater than 2. Additionally, the first SiO₂ layer is generated preferably by means of LPCVD (low-pressure chemical vapor deposition)-TEOS and the second SiO₂ layer is generated preferably by means of plasma-enhanced (PE) oxide deposition. Lastly, the second SiO₂ layer is preferably thicker than the first SiO₂ layer. As elucidated, instead of the two SiO₂ layers, it is also possible for only one single SiO₂ layer to be deposited.

The third insulator layer is deposited preferably as a silicon nitride auxiliary layer on the underlying SiO₂ layer, i.e., in particular the second SiO₂ layer when using three insulator layers.

In a further embodiment, the definition of the collector windows of the HS and of the HV transistors in step c comprises ablation of the silicon nitride auxiliary layer and of the second SiO₂ layer in the windows defined by means of a resist mask, by means of one or more dry etching steps, wherein an etching time in the dry etching step is adjusted such that an etch front is produced within the first SiO₂ layer.

With the process regime of the invention, the definition of the emitter window takes place in step e by means of a window in insulator layers of a further insulator layer stack over the cap layer. In one preferred embodiment, the insulator layer stack contains precisely three insulator layers. However, layer stacks of two or more than three insulator layers can also be used. One embodiment additionally comprises the implementation of an accelerated temperature treatment after the deposition of the insulator layer stack over the cap layer.

Then, in one embodiment with two or precisely three insulator layers in the insulator layer stack, the definition of the emitter window in step e comprises preferably steps as follows:
patterning of a PECVD oxide layer of the insulator layer stack by dry etching, preferably under etching conditions which cause little or no ablation of an adjacent silicon nitride layer of the insulator layer stack;
further opening of the silicon nitride layer, for example by an isotropic wet etching process for assisting widening of the opening toward the top.

A subsequent selective ion implantation for the formation of the HS-SIC doping and/or of the HV-SIC doping then takes place advantageously in a self-aligned way for the emitter window, wherein areas outside the emitter window are protected from the implantation by the insulator layer stack.

In a further embodiment, the silicon dioxide layer is deposited in step g by means of a low-pressure CVD procedure by means of a carrier gas which contains bis(tert-butylamino)silane.

Step j in the process of the invention comprises the deposition of an insulator layer sequence—to be differentiated from the insulator layer stack—and the patterning of this insulator layer sequence, the emitter layer and the insulator layer for forming a T-shaped emitter. In one advantageous embodiment of the invention, the emitter layer is patterned by means of the insulator layer sequence, which in this version is configured as a layer sequence of four individual layers comprising silicon oxide, silicon nitride, silicon oxide and silicon nitride. With this alternating sequence of silicon oxide and silicon nitride layers, instead of a single oxide layer or of a layer stack comprising silicon dioxide and silicon nitride, it is possible, even with variable height of the emitter polysilicon, to adapt the lateral and vertical thickness of the encapsulation of the emitter, independently of one another, to the requirements and simultaneously to ensure damage-free removal of the auxiliary layers.

A further advantageous embodiment of the invention affects the introduction of dopant into the external base area. Envisaged in accordance with the prior art are in situ dopings of the same conduction type as the base during the epitaxial reinforcement of the base terminal area, but also subsequently, by ion implantation. In contrast to earlier interpretations, relating to the prevention of implantation damage in the vicinity of the internal base area, a specific implantation of the external base areas prior to the epitaxial reinforcement is also included in the process of the invention claimed here. The process regime of this working example, after production of the lateral spacers at the side faces of the emitter and after the removal of the silicon nitride layer, and before the height extension of the base terminal layer, comprises the implementation of an oblique-angle implantation with wafer rotation, in order to provide near-surface regions of the base and of the cap layer, outside the internal transistor areas, with a high concentration of defects of the same conductivity type as the base.

A second aspect of the present invention, independent of the process regime described, constitutes a bipolar or BiCMOS semiconductor device comprising high-speed bipolar transistors, hereinafter HS transistors, and high-voltage bipolar transistors, hereinafter HV transistors. The device comprises:
a. a substrate having active areas and shallow trenchlike field isolation areas which laterally surround the active areas;
b1. in the active areas intended for the HV transistors, respectively a coherent highly conductive HV collector area of a first conductivity type; and
b2. in the active areas intended for the HS transistors, respectively a coherent highly conductive HS collector area of the first conductivity type;
c1. a first selective collector doping, hereinafter HV-SIC doping, which may also be present in the HS transistor areas, and
c2. an additional second selective collector doping, hereinafter HS-SIC doping, which is present exclusively in the HS transistors in the respective internal transistor area, where the dopings of the collector areas are selected such that the vertical extent of the base-collector space charge zone is greater in the HV transistor than in the HS transistor;
d. within the respectively same active area, surrounded by the same field isolation area, in which the respective base layer stack is arranged, a collector terminal area, which connects the collector area of the HS transistors and of the HV transistors to a collector contact;
e. in a collector window of the HV transistors and of the HS transistors that is bounded by insulator layers, respectively a base layer stack which comprises an epitaxial buffer layer, a monocrystalline, non-selectively epitaxially deposited base layer of a second conductivity type, opposite to the first, and a monocrystalline cap layer, where, owing to the non-selective epitaxial deposition of the base layer on the insulator layers in the region of the base layer and of the cap layer, a layer stack of a base terminal area, said stack following at least these layers in polycrystalline form, is arranged;
f. embedded into base-emitter spacer and into a further insulator layer of the HV transistors and of the HS transistors, respectively a highly doped, monocrystalline or polycrystalline, T-shaped emitter layer of the first conductivity type and lateral spacers at outward-facing side faces of the emitter layer and of the further insulator layer; and
g. outside the emitter of the HV transistors and of the HS transistors, respectively a height extension of the base terminal layer.

The device of the second aspect shares the advantages of the process regime of the first aspect. Firstly, the arrangement of the HV transistor known from the prior art, with an additional shallow field isolation area fabricated in STI technology and arranged between the internal transistor area and the collector contact, is replaced by a construction which corresponds in cross section to that of the high-speed transistor. In other words, in the active areas envisaged for the HV transistors, there is in each case only one coherent high-conductivity HV collector area of a first conductivity type. This embodiment of the device of the invention is notable for particularly low values for the collector resistance, the base-collector capacitance and the collector-substrate capacitance. Accordingly, both the high-voltage electric strength and radiofrequency properties are improved.

A further independent aspect of the invention constitutes a process for producing a bipolar or BiCMOS semiconductor device in accordance with the second aspect, which comprises high-speed bipolar transistors, hereinafter HS transistors, and high-voltage bipolar transistors, hereinafter HV transistors. The process comprises:
a. provision of a substrate having active areas and shallow trenchlike field isolation areas which laterally surround the active areas;
b1. in the active areas intended for the HV transistors: production respectively of a highly conductive HV collector area of a first conductivity type, which is bounded by a single frame formed by an individual field isolation area; and
b2. in the active areas intended for the HS transistors: production respectively of a highly conductive HS collector area of the first conductivity type, wherein the HS collector area is produced with a higher electrical conductivity by comparison with the HV collector area;
c. in a respective internal transistor area not only of the HS transistors but also of the HV transistors: introduction of a first selective collector doping, hereinafter HV-SIC doping;
d. exclusively in the internal transistor area of the HS transistors: introduction of an additional second selective collector doping, hereinafter HS-SIC doping;
e. deposition of insulator layers and production of a bordered collector window of the HV transistors and of the HS transistors in the insulator layers;
f. in the collector window of the HV transistors and of the HS transistors: deposition of a base layer stack which comprises an epitaxial buffer layer, a monocrystalline, non-selectively epitaxially deposited base layer of a second conductivity type, opposite to the first, and a monocrystalline cap layer, where, owing to the non-selective epitaxial deposition in the region of the base layer and of the cap layer, a layer stack of a base terminal area, said stack following at least these layers in polycrystalline form, is produced simultaneously on the insulator layers;
g. deposition of a further insulator layer;
h. production of a highly doped, monocrystalline or polycrystalline, T-shaped emitter layer of the first conductivity type, embedded into the further insulator layer, and production of lateral spacers at outward-facing side faces of the emitter layer and of the further insulator layer; and
j. production respectively of a height extension of the base terminal layer of the HV transistors and of the HS transistors.

Below, further working examples are described with reference to the drawings.

### BRIEF DESCRIPTION OF THE DRAWINGS

In the drawings:

FIG. 1 to FIG. 20 show a first working example of a process for producing bipolar transistors with nonselective base epitaxy and elevated base terminal area;

FIG. 21 to FIG. 25 show a second working example of a process for producing bipolar transistors with non-selective base epitaxy and elevated base terminal area.

### DETAILED DESCRIPTION OF WORKING EXAMPLES

The processes presented below, taking as the example for the production of npn bipolar transistors, embrace the realization of high-speed (HS) and high-voltage (HV) transistors. It should be noted that it is possible to omit fabrication of one of the two types without effects occurring in the case of the respective other type.

### Example 1

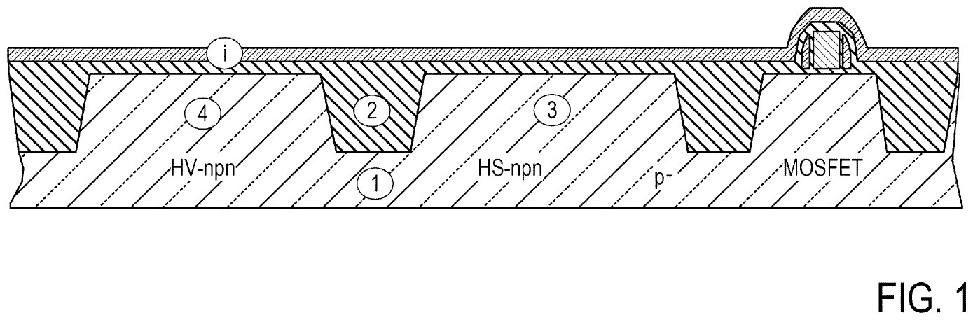

A first process for producing bipolar transistors with non-selective base epitaxy and elevated base terminal area is elucidated in reference to FIG. 1 to FIG. 20. In the subsequent figures, identical structural elements are denoted by identical numbers.

In particular, the process of the invention enables the production of high-speed and high-voltage bipolar transistors in integrated bipolar and BiCMOS procedures.

The process in the working example is a process for producing npn bipolar transistors on a p-conducting substrate 1. Patterned on the substrate 1 are active areas and a first kind of isolation areas 2. These isolation areas 2, referred to subsequently as field isolation areas, project from the substrate surface into the substrate area. The field isolation areas used may be what are called shallow trench isolations (STI). These are trenches with a depth of preferably 300 to 600 nm which may have been filled, for example, with silicon dioxide (SiO₂), or else with a combination of insulator material and polysilicon. Alternatively, field isolation areas produced by means of local oxidation (LOCOS) may be used.

In the CMOS areas, n-and p-conducting wells are produced and gates of polysilicon are patterned and provided with lateral spacers.

An auxiliary layer i is deposited on the Si wafers patterned as described. This auxiliary layer may be in particular a layer stack of different materials, more particularly comprising silicon dioxide and silicon nitride (FIG. 1).

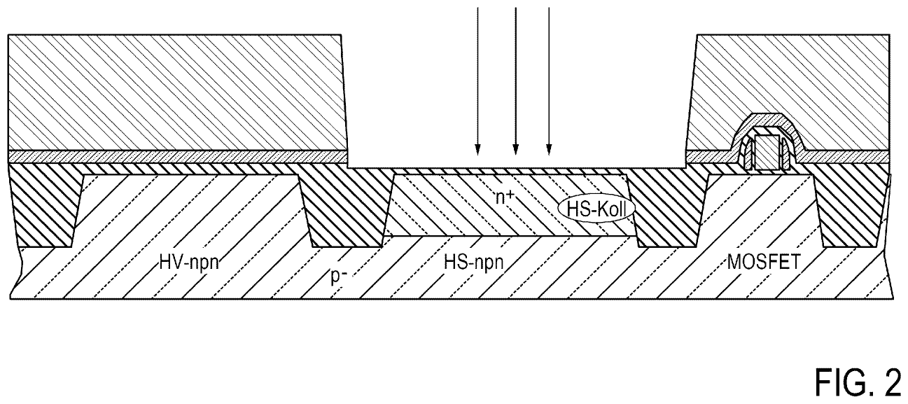

The auxiliary layer i is opened by means of a first resist mask over the active areas of the HS bipolar transistor 3 (FIG. 2). The patterning of the auxiliary layer i is accomplished by reactive ion etching (RIE), also referred to as dry etching. Prior to the removal of the resist mask, the highly n-conducting collector area of the HS transistor (HS-Koll) is generated by a masked ion implantation.

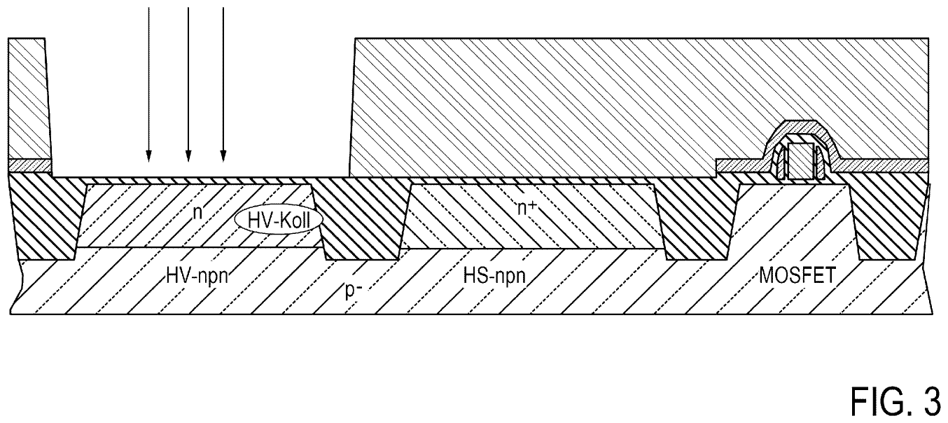

By means of a second resist mask, the auxiliary layer i over the area of the HV bipolar transistors 4 is removed, and a collector profile (HV-Koll) tailored to the demands on a high-voltage transistor is produced there by ion implantation (FIG. 3). The collector areas of the HS and HV transistors are bounded laterally by the isolation areas of the first kind. The STI bottom is preferably lower than the collector-side expansion of the collector-substrate space charge zone, in order to keep the collector-substrate capacitance low.

Following removal of the resist mask and customary wet-chemical cleaning steps, the collector implants are exposed by means of RTP to a heat treatment in order to carry out low-defect reconstruction of the crystal lattice of the Si substrate, which was disrupted during the collector implantation.

Optionally, the collector areas of the HS-HBTs 3 or of the HV-HBTs 4 may also be implanted locally before the deposition of the insulator layer i. In particular, the HS collector can be generated before the deposition of the layer i, and the HV collector can be introduced jointly with the opening of the layer i and of the resist mask used for that purpose.

Residual oxide layers on the active areas of the bipolar transistors are preferably removed before the subsequent insulator coatings.

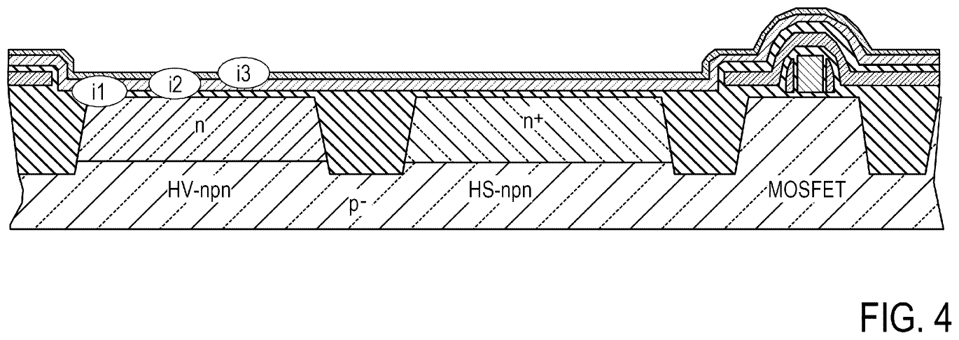

Subsequently, isolation areas of the 2nd kind are generated on the substrate surface. In the case of the invention, production starts with the deposition of two oxide layers i1 and i2 (FIG. 4). Layer i1 is an LPCVD-TEOS layer 15 nm to 100 nm thick, preferably 25 to 50 nm thick, or a deposition which is equivalent in terms of wet-chemical etching behavior, such as, for example, an atomic layer deposition coating (ALD). Deposited over this is a PECVD-SiO2 layer 25 nm to 100 nm, preferably 50 nm to 80 nm thick. The key reason for the use of a second oxide layer, lying above the TEOS, results from the possibility with PECVD oxides of being able to utilize a lower etching rate, by comparison with TEOS, in dilute hydrofluoric acid. One of the effects of the etching rate, lower by a factor of 1.5 to 3, is to widen the collector window when exposing the substrate surface. The other effect is that of the higher etching rate of TEOS, which brings about an overhang of the PECVD oxide. This overhang offers more favorable possibilities for filling the internal transistor areas, surrounded by the isolation areas of the 2nd kind, on subsequent selective epitaxy, in an extremely horizontally uniform way without gaps and dislocations, with Si. Further criteria for the suitability of a specific PECVD oxide are its edge coverage capacity, but also the seeding behavior during selective epitaxy.

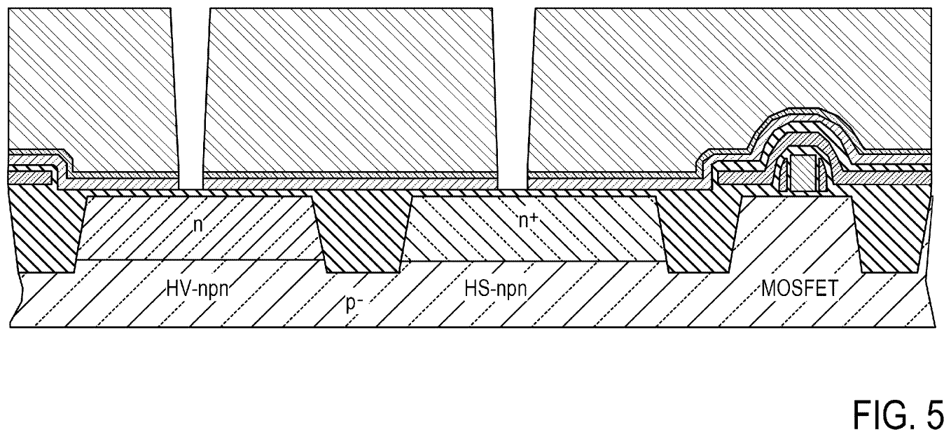

Deposited over the double-oxide stack is a silicon nitride (Si3N4) layer i3 with a thickness of 10 nm to 100 nm, preferably 20 nm to 50 nm. i3 serves as an auxiliary layer for the production of the internal transistor areas. By means of a photographically patterned resist mask, in the collector windows of both the HS and the HV transistors, the Si3N4 layer and the PECVD oxide layer are ablated via dry etching processes (FIG. 5) and the etching time in the RIE step is adjusted such that, at the end of the procedure, the etch front is located within the TEOS layer. As a result of this, effective decoupling of residual oxide thickness and widening of the collector window is achieved.

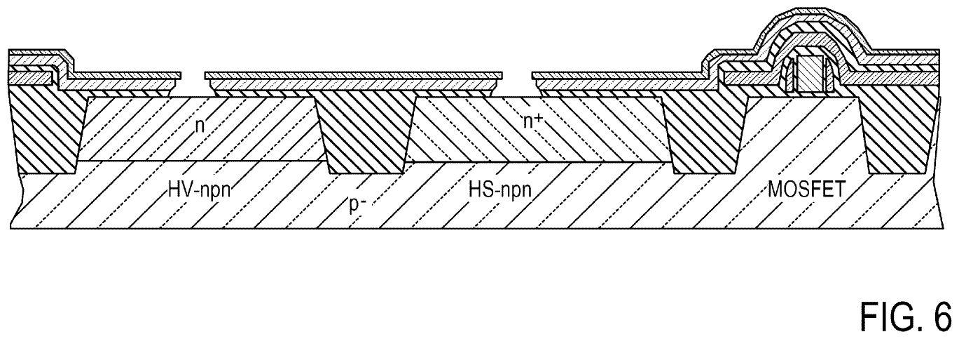

After removal of the resist mask, SiO2 in the collector window is ablated selectively to the silicon nitride, by means of wet-chemical processes which etch silicon dioxide, and the substrate surface is exposed there (FIG. 6). Subsequently, the silicon nitride layer i3 is removed selectively by wet-chemical means to form silicon dioxide, in hot phosphoric acid, for example.

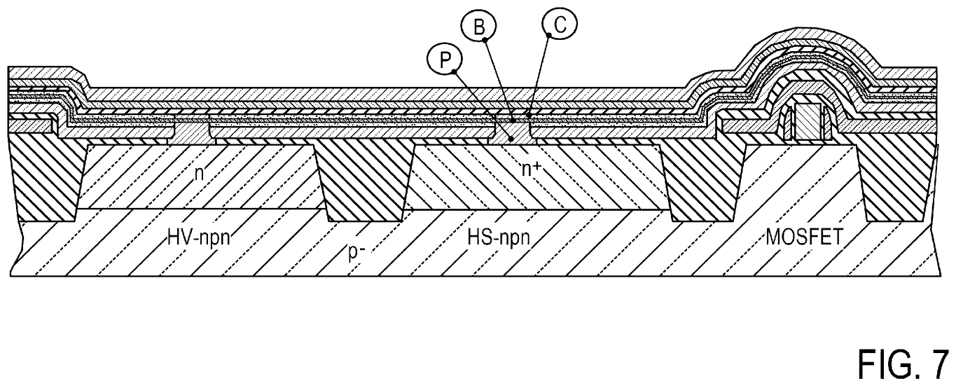

The buffer layer P of silicon is grown by selective epitaxy on the internal collector windows on the internal areas of the bipolar transistor that have been opened accordingly, after which the monocrystalline base layer B and the monocrystalline Si cap layer C are generated with a non-selective epitaxy step. The base layer B may in particular comprise an SiGe layer and a doping with carbon. The p doping of the intrinsic base is introduced in situ during layer growth. A polycrystalline Si/SiGe/Si layer stack grows on the exposed isolation areas 2 (FIG. 7).

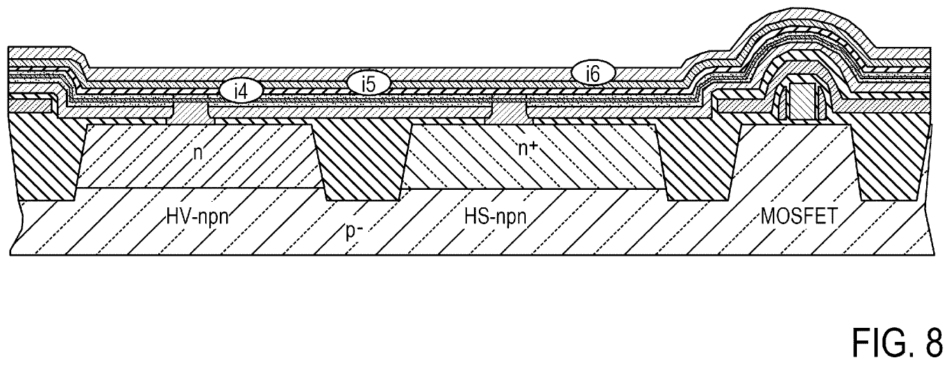

Deposited over the cap layer C is a layer stack consisting of a silicon dioxide layer i4, a silicon nitride layer i5 and a PECVD oxide layer i6 (FIG. 8). The auxiliary layer i4 consists preferably of an LPCVD-TEOS layer, having a thickness for example of 3 nm to 20 nm, i5 of a silicon nitride layer having a thickness for example of 30 nm to 100 nm. The thickness of the PECVD oxide layer i6 may be for example from 50 nm to 150 nm. The stack i4, i5 and i6 is subjected to an accelerated temperature treatment. This treatment employs temperatures of less than 850° C., preferably less than 750° C., and times of less than 5 minutes. The use according to the invention of PECVD silicon dioxide as cap layer i6 and the accelerated temperature treatment of said layer are aimed at reducing the widening of the emitter window in subsequent wet-chemical procedures.

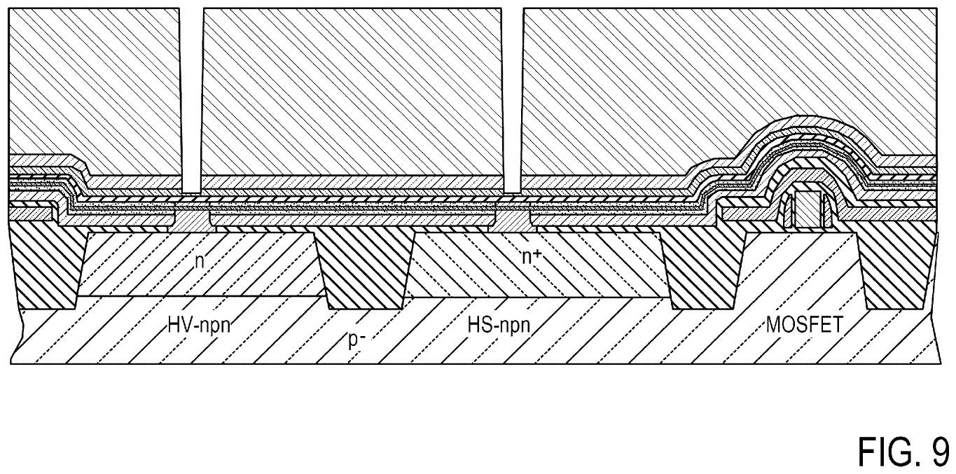

By means of a resist mask, a window, defining the active emitter domain, is opened in the insulator layers i5 and partially in i6 (FIG. 9). This window is also referred to as the emitter window. The patterning of the insulator layer i6 is accomplished by RIE. Up until the silicon nitride layer i5 is reached, this anisotropic dry etching preferably utilizes etching conditions which cause little or no ablation of i5. The resist mask is subsequently removed and the auxiliary layer i5 is opened further, by an isotropic wet etching process, for example. The wet etching process selectively etches the layer i5 of silicon nitride, but not the layers i4 and i6, which consist of silicon dioxide. As a result of the isotropic etching, the widening of the opening of the auxiliary layer i5, shown in FIG. 9, toward the top is assisted.

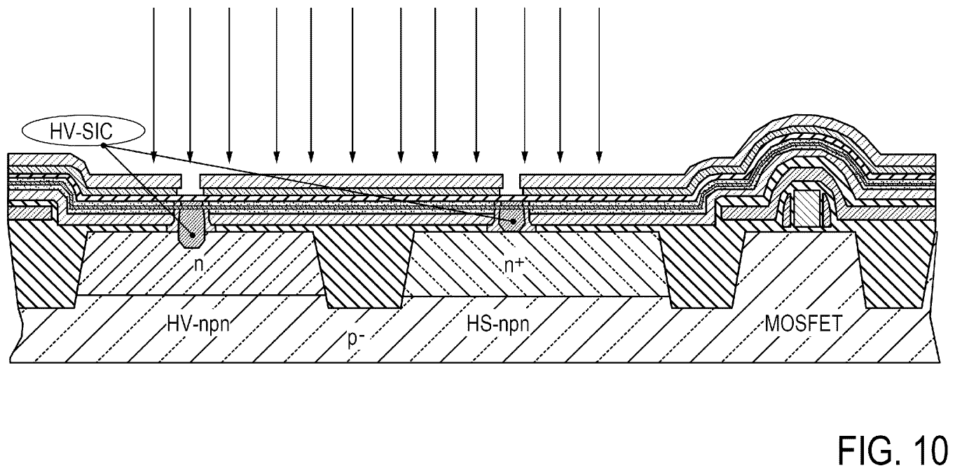

In one configuration of the invention, an ion implantation of the same type as the collector, and suitable for the purposes of the HV transistor, is introduced at this point (FIG. 10). This implantation does not bring any disadvantages for the HS transistors which are exposed at the same time. The additional collector doping HV-SIC is self-aligned for the emitter window, since areas outside the emitter window are protected from the implantation by the stack i4, i5 and i6.

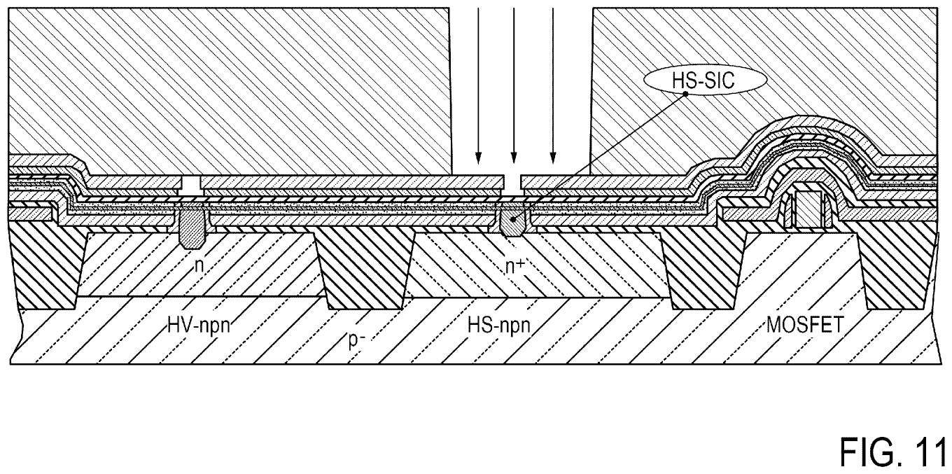

Conversely, a resist mask which is only opened over the HS emitter windows shields the HV areas when the HS-SIC doping for the emitter window (HS-SIC) is introduced, again in a self-aligning manner (FIG. 11).

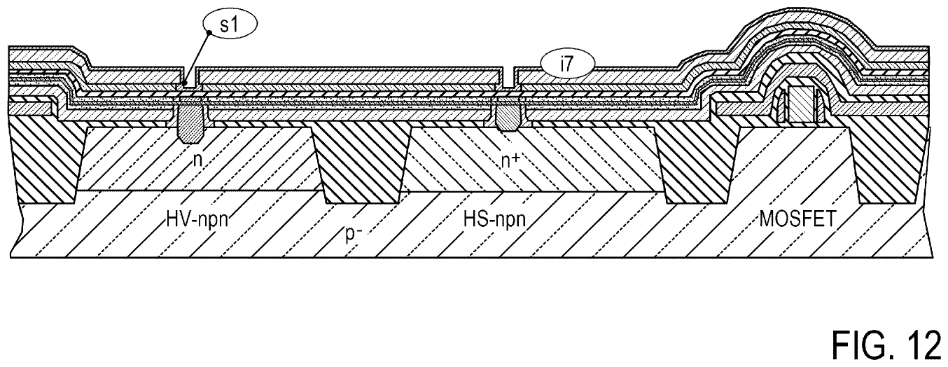

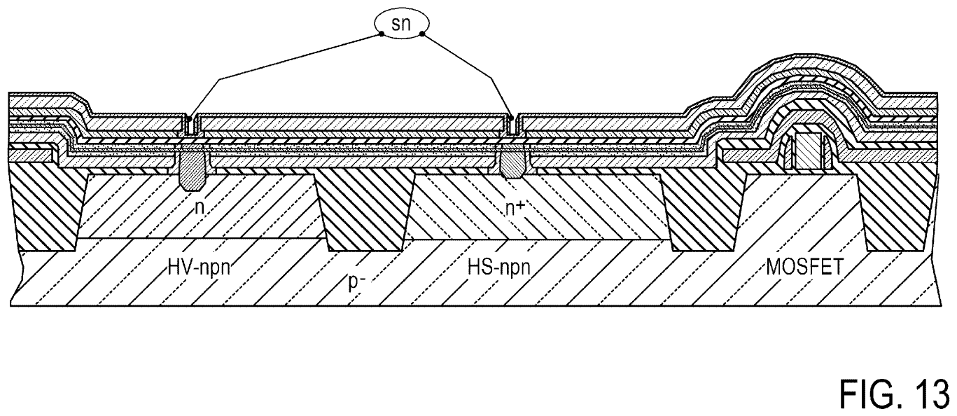

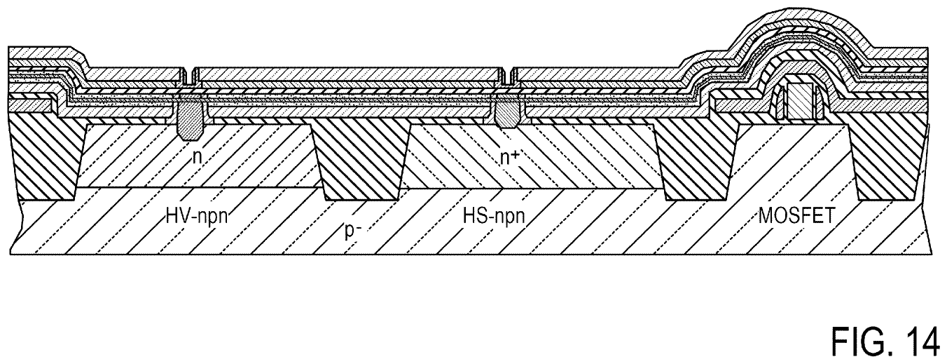

In a further step, an insulator layer i7 is deposited which consists of a specific silicon dioxide layer and has a thickness of 30 nm to 70 nm (FIG. 12). This LPCVD deposition, based on the carrier gas BTBAS, possesses the advantage that the resulting etching rate in dilute hydrofluoric acid is smaller by a factor of up to 2. This significant advantage for the configuration according to the invention is also not substantially diminished by the recommended healing in the temperature range up to about 650° C. immediately after the BTBAS oxide procedure. The insulator layer i7 is partially back-etched by means of an anisotropic RIE procedure, with spacers s1 being formed within the opened emitter window (FIG. 12). The width of these SiO₂ spacers is determined firstly by the deposition thickness of the layer i7, but also, secondly, by the lateral, wet-chemical back-etching of the silicon nitride auxiliary layer i5 in hot phosphoric acid. The formation of the base-emitter spacer is continued with the deposition of an Si3N4 layer, which may preferably possess a thickness of 15 nm to 50 nm, and with the anisotropic RIE etching of this layer (FIG. 13). The end of the etching operation is initiated by a so-called endpoint mechanism which responds to the degree of ablation of Si3N4, thereby securing the reproducibility of the etching depth. The resultant silicon nitride auxiliary spacer sn protects the interior sidewall of the oxide spacer s1 from attack in the subsequent wet-chemical SiO2 etching, in which the substrate surface is exposed in the emitter window (FIG. 14). Subsequently, the Si3N4 spacer is removed selectively in hot phosphoric acid to form SiO2.

By means of the procedural changes according to the invention, consisting of the use of PECVD oxide as insulator layer i6 with additional RTP treatment, the usage of a more etch-stable spacer material based on BTBAS oxide, the application of an anisotropic intermediate RIE etching in combination with the formation of an Si3N4 auxiliary spacer, success is achieved, in comparison to the prior art, in producing narrower emitter widths together with adaptively smaller base-emitter spacers. Moreover, close to the surface, a steeper profile of the side interior wall of the emitter-base spacer is produced, formed of the insulator layers i4 and i7, which replaces the customary shape, running out shallowly at the side toward the emitter window, with wet-chemical etching-up of a homogeneous oxide layer.

In a further step, the emitter E is deposited epitaxially. The emitter consists preferably of silicon, which is provided in situ with an n+ doping, preferably arsenic. In the region of the emitter window, the emitter may be monocrystalline or polycrystalline. Prior to the epitaxy step, it is common to employ wet cleaning in dilute hydrofluoric acid in order to remove thin oxide layers over the silicon surface in the emitter window and to saturate free bonds with hydrogen at the Si surface. It is not unusual for a temperature treatment between 800° C. and 900° C. to be performed in the epitaxy reactor, before the deposition phase, in order to eliminate residual oxygen between cap layer and emitter layer in the emitter window. In one configuration of the invention, this temperature loading is omitted. In combination with an extensive enrichment with arsenic at the surface of the cap layer C at the start of the Si epitaxy, it is possible in this way to achieve low depths of penetration of the As emitter doping and hence smaller emitter-base edge capacitances and also small emitter resistances.

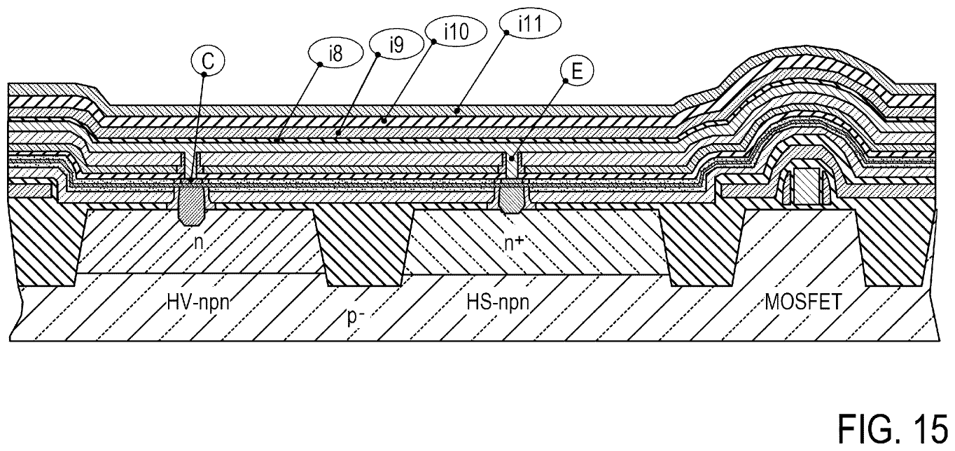

Deposited above the emitter layer in accordance with the invention is a four-way stack i8, i9, i10 and i11, consisting alternately of silicon dioxide and silicon nitride (FIG. 15). The silicon dioxide layer i8 preferably has a thickness of 5 nm to 25 nm; the silicon nitride layer i9 lying over it may be preferably 30 nm to 70 nm thick; the thicknesses of i10 and i11 are between 20 nm and 80 nm.

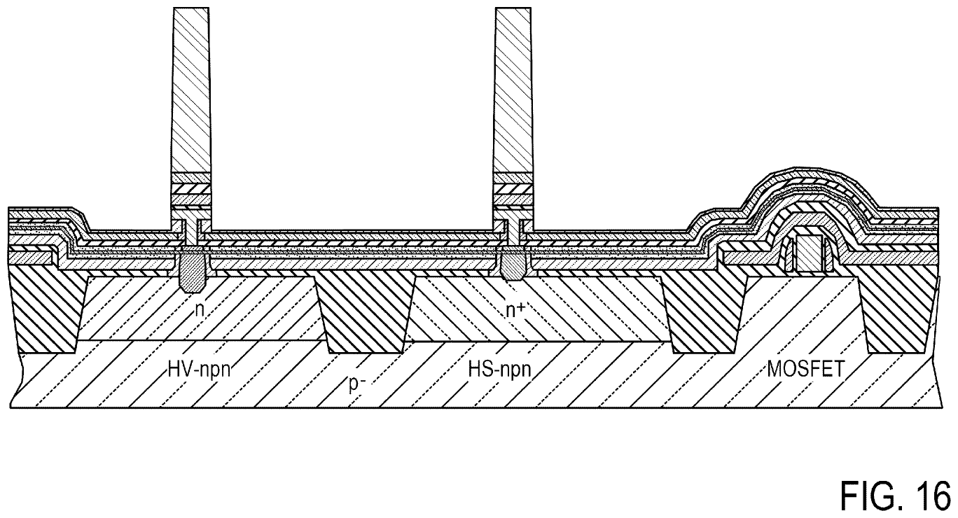

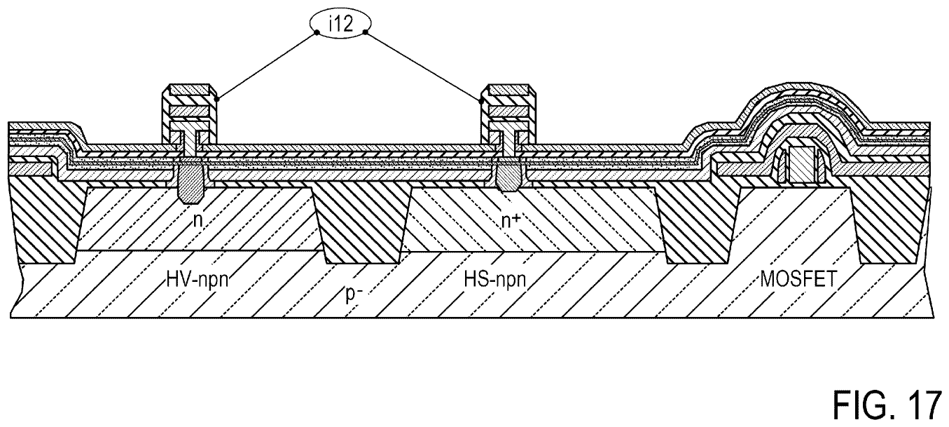

The emitter layer E, the insulator layers i8, i9, i10 and i11, and, in the preferred course, in part i6 as well are patterned in a further step by way of a resist mask (FIG. 16). Subsequently, at the laterally outward-facing side faces of the emitter, spacers i12 are produced which consist for example of silicon dioxide. In the subsequent spacer etching, the auxiliary layer i5 can be utilized as a stopping layer (FIG. 17).

The Si3N4 auxiliary layers i5 and i11 are subsequently ablated for example in hot phosphoric acid. This selective wet etching procedure removes i5 and i11, but not the emitter jacketing s1, i6, i12 and i11, formed of silicon dioxide, and also not the remnants of the layer i4 consisting of SiO2.

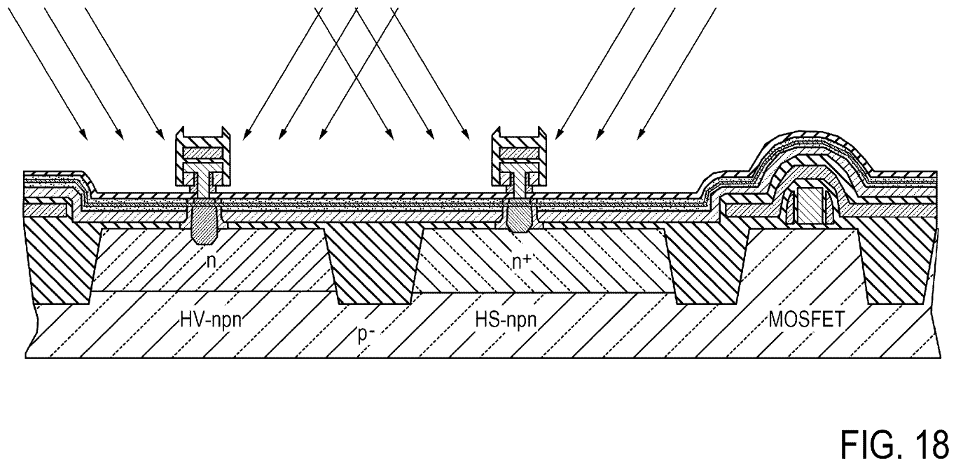

In one configuration of the invention, in this state, an oblique-angle implantation with wafer turning is utilized so as to provide the near-surface regions of the SiGe base and Si cap layer, outside of the internal transistor areas, with a high concentration of defects of the same conductivity type as the base. Preference is given to using an electrically neutral variety of ion to render the near-surface Si layer amorphous, in order to prevent channeling in subsequent implantations (FIG. 18). An implantation at this point in the course of the procedure is deemed to be risky, owing to the danger of increased diffusion or formation of defects of the in-range base doping, and has been shunned in the presence of an epitaxial reinforcement of the external base areas. Studies, however, have shown that by means of the stated implantation conditions, success is achieved in further reducing the base resistance and at the same time attaining perceptible advantages in the high-speed characteristics.

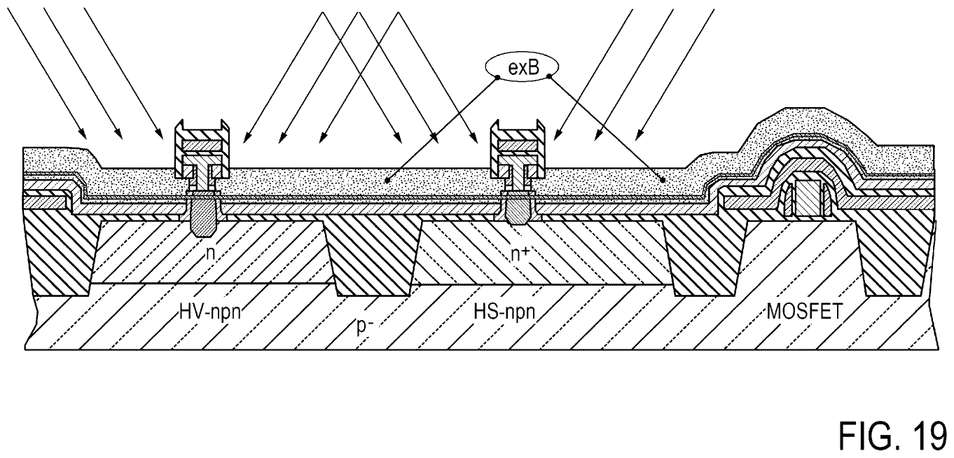

The surface of the cap layer C is exposed by wet etching in the regions outside of the emitter, i.e., on the external base terminal areas. The elevated base terminal layer exB is grown by means of selective epitaxy on the exposed surface of the cap layer C (FIG. 19). The p doping of the base terminal layer, preferably pre-doped in situ during the epitaxy step, is preferably further increased by ion implantation. The energy and the incident angle of the implanted ions here are selected such that their depth of penetration, in the transistor area laterally surrounded by the isolation areas of 2nd kind, is restricted to the region above the maximum of the doping of the epitaxial base layer B, in order to avoid an increase in the base-collector capacitance. Furthermore, the elevated base terminal areas lying above the isolation areas of 2nd kind are furnished largely entirely with a high dopant concentration. For this, a vertical or almost vertical implantation direction is employed, with the internal transistor area, including the emitters, being protected by the encasement of the emitter layer.

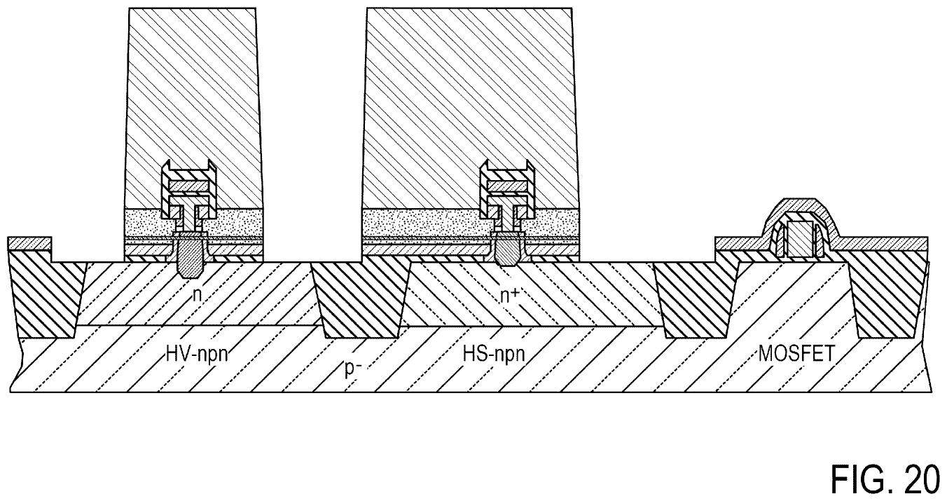

In a further step, the epitaxial layers P, B, C and exB are removed completely from the collector terminal areas and from the CMOS areas by means of a further resist mask. This can be accomplished by utilizing an RIE procedure which stops on the auxiliary layer i2. Subsequently, the auxiliary layers i1 and i2 are removed (FIG. 20). The CMOS areas are therefore back in the same state as before the deposition of the auxiliary layer i1 and i2.

In a BiCMOS procedure, in the subsequent procedural steps, the source-drain areas of the MOS transistors are doped in accordance with the known prior art.

### Example 2

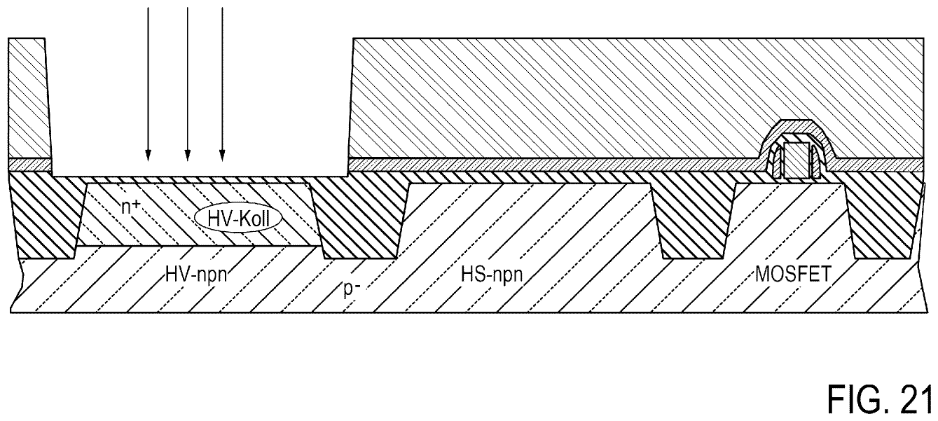

A second process for producing bipolar transistors with non-selective base epitaxy and elevated base terminal areas is elucidated below with reference to FIGS. 21 to 25. It differs from the process described in Example 1 essentially in the production of the selectively implanted collector areas of the high-speed (HS-SIC) and high-voltage (HV-SIC) transistors. The subsequent description concentrates on differences in the process regime.

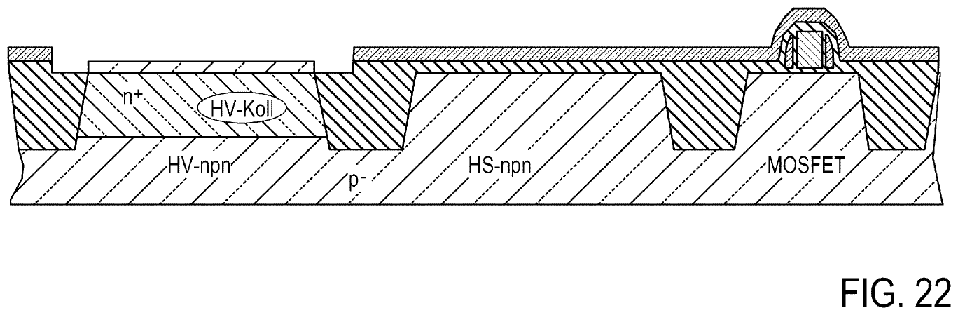

Up to the point of deposition of the auxiliary layer i, the process is identical to the process described in Example 1. The auxiliary layer i is subsequently opened by means of a first resist mask over the active areas of the HV bipolar transistor. The auxiliary layer i is patterned by reactive ion etching and, still before the removal of the resist mask, the n-conducting collector area of the HV transistor (HV-Koll) is generated through a masked ion implantation (FIG. 21). In one configuration of the invention, after the removal of the resist mask, in the exposed collector areas of the HV transistors, by means of selective epitaxy, an undoped or weakly n-doped Si layer is deposited in a thickness of for example 10 nm to 80 nm, preferably 10 nm to 40 nm (FIG. 22). This layer serves to increase the width of the base-collector space charge zone and hence to increase the breakthrough voltage of the HV transistor.

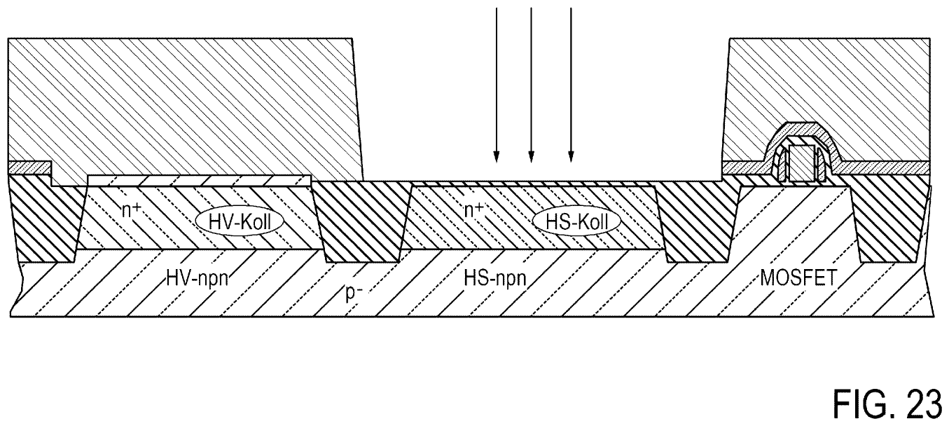

By means of a second resist mask, the auxiliary layer i is removed over the area of the HS bipolar transistors and the collector areas (HS-Koll) for the high-speed transistors are produced there by ion implantation (FIG. 23). Following removal of the resist mask and customary wet-chemical cleaning steps, the collector implants are exposed by means of RTP to a heat treatment in order to carry out low-defect reconstruction of the crystal lattice of the Si substrate, which was disrupted during the collector implantation.

In one configuration of the invention, the above-described collector areas (HS-Koll) are used both for the fabrication of the high-speed transistors (HS) and for transistors with increased breakthrough voltages (HV). The further differentiation of the two types of transistors is accomplished in this configuration by the realization of selectively implanted collector regions HS-SIC and HV-SIC, adapted to the requirements of the respective transistor type, with the processes described below.

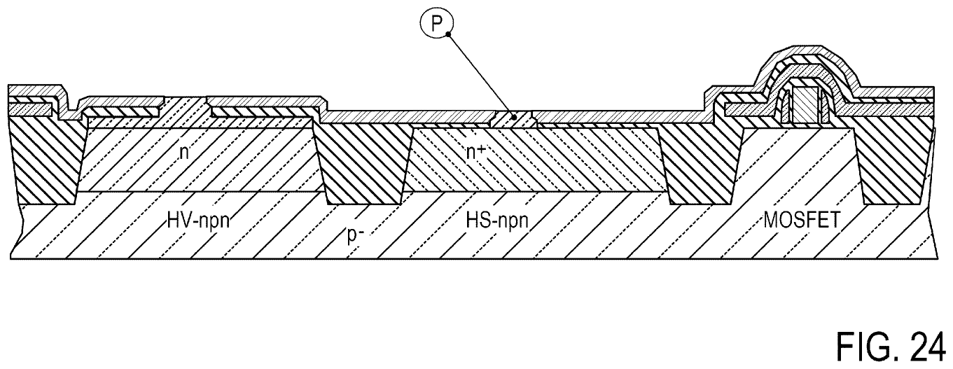

Following the production of the collector areas HV-Koll and HS-Koll, isolation areas of 2nd kind are generated on the substrate surface as in Example 1. After the opening of the internal areas of the bipolar transistors (FIG. 24), selective epitaxy is used to grow the buffer layer P of silicon on the internal collector windows. In contrast to Example 1, after the deposition of this buffer layer P, additional dopings of the collector areas by ion implantation are generated, which meet the differing requirements of the HS and HV transistors.

In one configuration of the invention, it is possible at this point to introduce an ion implantation of the collector type, suitable for the purposes of the HV transistor, without further masking. This implantation does not bring any disadvantages for the simultaneously exposed HS transistors. Moreover, the implantation energy is selected such that the layer stack lying over the CMOS areas, composed of the auxiliary layer i and the insulator layers i1 and i2, is not penetrated by the ions.

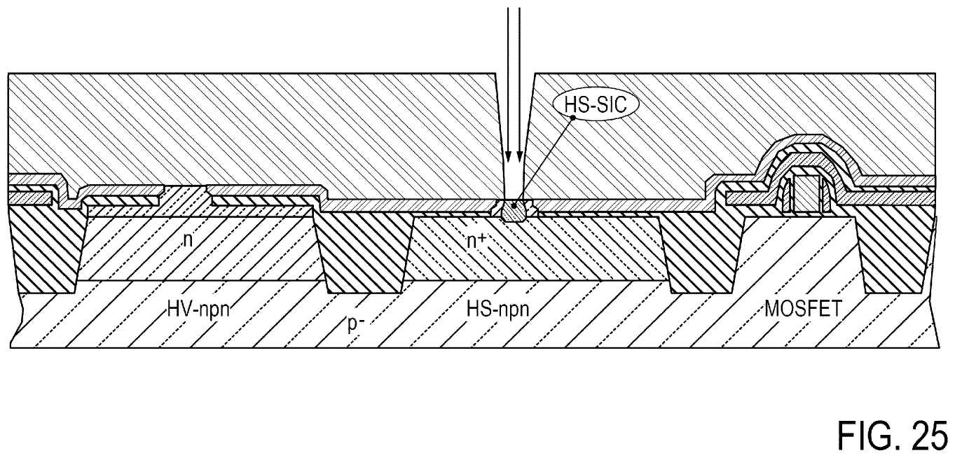

Selectively implanted collector areas of the high-speed transistors (HS-SIC) are implanted by means of a resist mask (FIG. 25). The lateral boundaries of the implanted HS-SIC areas are defined by the edges of the resist mask, which is aligned with high accuracy to the isolation areas of 2nd kind. As a result, the possibility exists of optimizing the lateral extent of the HS-SIC areas independently of the other critical transistor dimensions for optimal radiofrequency properties of the HS transistors. Following removal of the resist mask and customary wet-chemical cleaning steps, a heat treatment takes place by means of RTP in order to carry out low-defect reconstruction of the crystal lattice, which was disrupted during the implantation.

Subsequently, the monocrystalline base layer B and the monocrystalline Si cap layer C are generated with a non-selective epitaxy step. The base layer B may in particular comprise an SiGe layer and a doping with carbon. The p-doping of the intrinsic base is introduced in situ during the layer growth. As in Example 1, a polycrystalline Si/SiGe/Si layer stack grows on the exposed isolation areas 2.

Thereafter, as in Example 1, a layer stack consisting of the layers i4, i5 and i6 is deposited and emitter windows are opened (FIG. 8, 9). In one configuration of the invention, at this point an ion implantation of the collector type, suitable for the purposes of the HV transistor, is introduced (FIG. 10). This implantation does not bring any disadvantages for the simultaneously exposed HS transistors.

An insulator layer i7 is then deposited (FIG. 12) and the fabrication procedure is continued as in Example 1.

The application of the construction details or process steps of the invention is not restricted to the technology variant employed in the description examples. It is obvious at points where, in the context of analogous problem scenarios, the solutions claimed here lead to the improvements targeted.

What is claimed is:

1. A process for producing high-speed bipolar transistors, hereinafter HS transistors, or/and high-voltage bipolar transistors, hereinafter HV transistors, as part of the implementation of a bipolar or BiCMOS production procedure, comprising:
a. provision of a substrate having active areas and shallow trenchlike field isolation areas which surround the active areas;
b. subsequently, optionally:
b1. implementation of a masked first ion implantation for forming a high-conductivity HV collector area of a first conductivity type in the active areas intended for the HV transistors; or/and
b2. implementation of a masked second ion implantation for forming a high-conductivity HS collector area of the first conductivity type in the active areas intended for the HS transistors;
c. deposition of insulator layers on the substrate surface and definition of collector windows as internal transistor areas of the HS and HV transistors;
d. selective epitaxial deposition of a buffer layer in the collector windows thus defined, and subsequently non-selective epitaxial deposition of a monocrystalline base layer of a second conductivity type, opposite to the first, and of a monocrystalline cap layer on the buffer layer, where during the non-selective epitaxial deposition, a polycrystalline layer stack grows at the same time on the insulator layers, and where the deposition of the buffer layer, the base layer and the cap layer takes place in one joint or in two separate epitaxy steps;
e. deposition of an insulator layer stack over the cap layer and subsequent definition of an active emitter domain, referred to hereinafter as emitter window, by opening of a window in insulator layers of the insulator layer stack;
f. implementation of ion implantations of the same doping type as the collector for the formation of selectively implanted collector areas of the HS transistors, hereinafter HS-SIC doping, and/or of selectively implanted collector areas of the HV transistors, hereinafter HV-SIC doping, optionally after the deposition of the buffer layer, if the depositions in step d are performed in two separate epitaxy steps, or after opening of the emitter windows in step e, comprising
f1. selective ion implantation in internal collector areas of the HS transistors where provided, the HV transistors where provided being protected from the implantation by a resist mask or by the insulator stack,
f2. selective ion implantation in internal collector areas of the HV transistors where provided, the HS transistors where provided being optionally covered by a resist mask or likewise undergoing this implantation of the internal collector areas,
f3. choice of the implantation conditions in such a way that a vertical extent of the base-collector space charge zone in the HV transistor is greater than in the HS transistor;
g. deposition of a silicon dioxide layer and formation of base-emitter spacers within the emitter window by partial anisotropic back-etching of the silicon dioxide layer by means of a dry etching process, and formation of auxiliary spacers in the emitter window by deposition of a silicon nitride layer and subsequent anisotropic back-etching with stopping on the remaining part of the silicon dioxide layer;
h. exposure of a surface in the emitter window, formed by the cap layer, and subsequent removal of the auxiliary spacers;
i. epitaxial deposition of a highly doped, monocrystalline or polycrystalline emitter layer of the first conductivity type;
j. deposition of an insulator layer sequence and patterning of the insulator layer sequence, the emitter layer and the insulator layer for forming a T-shaped emitter, and production of lateral spacers at the outward-facing side faces of the emitter layer and of the insulator layer;
k. exposure of the cap layer in regions outside the emitter and selective epitaxy of a height extension of a base terminal layer of the polycrystalline layer stack with in situ doping of the same conduction type as the base; the conductivity of the base terminal layer may optionally be increased by a following ion implantation;
l. patterning of the parts of the buffer, base, cap and heightened base terminal layers deposited on the base terminal areas, for the removal of said layers from collector terminal areas.

2. The process as claimed in claim 1, in which after the formation of the collector areas of the HV or/and HS transistors, in step b, additionally, a silicon buffer layer is selectively epitaxially deposited on the exposed collector areas.

3. The process as claimed in claim 1, in which the ion implantations of the collector areas of the HS-HBTs and of the HV-HBTs are implemented such that a border of a collector-substrate space charge zone is embodied less deep in the substrate on the side of said zone lying closer to the substrate surface than a bottom of the field isolation areas.

4. The process as claimed in claim 1, in which the crystal lattice of the Si substrate, disrupted during the collector implantation, undergoes low-defect reconstruction by means of a heat treatment.

5. The process as claimed in claim 1, in which the production of the isolation areas comprises the deposition initially of a first SiO₂ layer and thereafter of a second SiO₂ layer, which is more etch-stable with respect to wet etching in dilute hydrofluoric acid, wherein
a) the ratio of the etching rates of the layers and is greater than 1.5, preferably greater than 2;
b) the layer is generated preferably by means of low-pressure CVD-TEOS and the layer is generated preferably by means of plasma-enhanced oxide deposition;
c) the layer is preferably thicker than the layer.

6. The process as claimed in claim 5, further comprising
deposition of a silicon nitride auxiliary layer on the second SiO₂ layer for the production of the internal transistor areas.

7. The process as claimed in claim 6, in which the definition of the collector windows of the HS and of the HV transistors comprises:
ablation of the silicon nitride auxiliary layer and of the second SiO₂ layer in the windows defined by means of a resist mask, by means of one or more dry etching steps, wherein an etching time in the dry etching step is adjusted such that an etch front is produced within the first SiO2 layer.

8. The process as claimed in claim 1, comprising:
implementation of an accelerated temperature treatment after the deposition of the insulator layer stack over the cap layer.

9. The process as claimed in claim 1, in which the definition of the emitter window comprises:
patterning of a PECVD oxide layer of the insulator layer stack by dry etching, preferably under etching conditions which cause little or no ablation of an adjacent silicon nitride layer of the insulator layer stack;
further opening of the silicon nitride layer, for example by an isotropic wet etching process for assisting widening of the opening toward the top.

10. The process as claimed in claim 9, further comprising:
implementation of the selective ion implantations for the formation of the HS-SIC doping and/or of the HV-SIC doping in a self-aligned way for the emitter window, wherein areas outside the emitter window are protected from the implantation by the insulator layer stack.

11. The process as claimed in claim 1, in which the silicon dioxide layer is deposited in step g by means of a low-pressure CVD procedure by means of a carrier gas which contains bis(tert-butylamino)silane.

12. The process as claimed in claim 1, in which the insulator layer sequence is configured as a layer sequence of four individual layers of silicon oxide, silicon nitride, silicon oxide and silicon nitride.

13. The process as claimed in claim 1, comprising, after production of the lateral spacers at the side faces of the emitter and after the removal of the silicon nitride layer i5 and before the height extension of the base terminal layer:
implementation of oblique-angle implantation with wafer rotation, to provide near-surface regions of the base and of the cap layer, outside the internal transistor areas, with a high concentration of defects of the same conductivity type as the base.

14. A bipolar or BiCMOS semiconductor device comprising high-speed bipolar transistors, hereinafter HS transistors, and high-voltage bipolar transistors, hereinafter HV transistors, comprising:
a. a substrate having active areas and shallow trenchlike field isolation areas which laterally surround the active areas;
b1. in the active areas intended for the HV transistors, respectively a coherent highly conductive HV collector area of a first conductivity type; and
b2. in the active areas intended for the HS transistors, respectively a coherent highly conductive HS collector area of the first conductivity type;
c1. a first selective collector doping, hereinafter HV-SIC doping, which may also be present in the HS transistor areas, and
c2. an additional second selective collector doping, hereinafter HS-SIC doping, which is present exclusively in the HS transistors in the respective internal transistor area, where the dopings of the collector areas are selected such that the vertical extent of the base-collector space charge zone is greater in the HV transistor than in the HS transistor;
d. within the respectively same active area, surrounded by the same field isolation area, in which the respective base layer stack is arranged, a collector terminal area, which connects the collector area of the HS transistors and of the HV transistors to a collector contact;
e. in a collector window of the HV transistors and of the HS transistors that is bounded by insulator layers, respectively a base layer stack which comprises an epitaxial buffer layer, a monocrystalline, non-selectively epitaxially deposited base layer of a second conductivity type, opposite to the first, and a monocrystalline cap layer, where, owing to the non-selective epitaxial deposition of the base layer on the insulator layers in the region of the base layer and of the cap layer, a layer stack of a base terminal area, said stack following at least these layers in polycrystalline form, is arranged;
f. embedded into base-emitter spacers and into a further insulator layer of the HV transistors and of the HS transistors, respectively a highly doped, monocrystalline or polycrystalline, T-shaped emitter layer of the first conductivity type and lateral spacers at outward-facing side faces of the emitter layer and of the further insulator layer; and
g. outside the emitter of the HV transistors and of the HS transistors, respectively a height extension of the base terminal layer.
